(19) United States
(12) Patent Application Publication
(10) Pub. No.: US 2002/0182857 A1
(43) Pub. Date: Dec. 5, 2002

(54) Damascene process in intergrated circuit fabrication

(76) Inventors: Chih-Chien Liu, Taipei (TW); Hsueh-Chung Chen, Taipei Hsien (TW); Chiung-Sheng Hsiung, Hsinchu (TW); Tong-Yu Chen, Hsinchu (TW)

Correspondence Address: CHARLES C.H. WU & ASSOCIATES, Suite 710, 7700 IRVINE CENTER DRIVE, Irvine, CA, 92618-3043, US

(21) Appl. No.: 09/870,440

(22) Filed: May 29, 2001

(51) Int. Cl. H01L 21/4763; H01L 21/44

(52) U.S. Cl. 438/645; 438/644; 438/654; 438/631

(57) ABSTRACT

A damascene process for forming a via that leads to a conductive layer on a substrate. A low dielectric constant material layer is formed over the substrate. A low temperature hard mask layer is formed over the low dielectric constant material layer. The low temperature hard mask layer is patterned to form an opening above the conductive layer. Using the low temperature hard mask layer as a mask, the exposed low dielectric constant material layer is etched to form a via hole. An adhesion promoter liner is formed on the interior walls of the via hole. Metallic material is deposited into the via hole to form a via.

### BACKGROUND OF THE INVENTION

1. Field of Invention

The present invention relates to a method for fabricating an integrated circuit. More particularly, the present invention relates to a damascene process for fabricating an integrated circuit.

2. Description of Related Art

Damascene process is a method of fabricating multi-level interconnects. The method includes forming a via hole or a trench in a dielectric layer and then filling metallic material into the via hole or trench to form a via or a conductive line. Because metallic material is difficult to etch, conventional deposition and patterning method cannot be used. Due to rapid increase in the level of integration, resistance-capacitance delay (RC delay) of devices must be reduced to increase overall operating speed of an integrated circuit. Therefore, low dielectric constant material is used to form inter-layer dielectric between neighboring metallic layers. Furthermore, copper is the principle metallic material due to a relatively small resistance.

FIGS. 1A through 1C are schematic cross-sectional views showing the steps carried out in a conventional damascene process for forming a copper via. As shown in FIG. 1A, a substrate 100 having a copper layer 102 thereon is provided. A passivation layer 104 is formed over the substrate 100. A low dielectric constant material layer 110 is formed over the passivation layer 104. A silicon oxide hard mask layer 120 is formed over the material layer 1 10. A patterned photoresist layer 130 is formed over the silicon oxide hard mask layer 120. The patterned photoresist layer 130 includes an opening 132 over the copper layer 102. The oxide hard mask layer 120 is patterned using the photoresist layer 130 as a mask.

As shown in FIG. 1B, using the photoresist layer 130 and the silicon oxide hard mask layer 120 as a mask, the exposed low dielectric constant material layer 110 is etched to form a via hole 140. Residual photoresist layer 130 is removed and then passivation layer 104 at the bottom of the via hole 140 is removed to expose a portion of the copper layer 102. A conformal barrier layer 166 is formed over the substrate 100. Copper is deposited over the substrate 100 and completely filled the via hole 140.

Finally, as shown in FIG. 1C, copper material and barrier material outside the via hole 140 layer 180 and barrier layer 166 are removed to form a complete copper via 180a.

The aforementioned conventional damascene process has a few drawbacks. As shown in FIG. 1A, the silicon oxide hard mask layer 120 needs to be formed at a temperature greater than 400° C. In general, the low dielectric constant material is organic and has a low heat resistant capacity. Hence, physical and chemical properties of the low dielectric constant material may change leading to a drop in quality of the copper via 180a and stability of the resistance. In addition, as shown in FIG. 1B, out-gassing from the low dielectric constant material layer 110 may occur after the formation of the via hole 140. The out-gassing not only may impede subsequent deposition of the barrier layer 166, but may also form air bubbles 168 between the low dielectric constant layer 110 and the barrier layer 166 inside the via hole 140. Ultimately, when copper material is deposited into the via hole 140 in a subsequent step, the air bubbles 168 may affect the final quality of the copper via 180a. This phenomenon is commonly referred to as ‘via poisoning’. Furthermore, if the temperature for forming the silicon oxide hard mask layer 120 is too high, a portion of the material in the low dielectric constant material layer 110 may dissociate leading to severe out-gassing later.

### SUMMARY OF THE INVENTION

Accordingly, one object of the present invention is to provide a damascene process for forming a via that leads to a conductive layer on a substrate. A low dielectric constant material layer is formed over the substrate. A low temperature hard mask layer is formed over the low dielectric constant material layer. The low temperature hard mask layer is patterned to form an opening above the conductive layer. Using the low temperature hard mask layer as a mask, the exposed low dielectric constant material layer is etched to form a via hole. An adhesion promoter liner is formed on the interior walls of the via hole. Finally, metallic material is deposited into the via hole to form a via.

This invention also provides a dual damascene process for forming a via and a conductive line over a substrate such that the conductive line is electrically connected to a conductive layer in a substrate through the via. The process of forming the via hole is identical to the aforementioned damascene process. After the via hole is formed, a trench that crosses the via hole is formed in the low temperature hard mask layer and the low dielectric constant material layer. An adhesion promoter liner is formed on the interior sidewalls of the via hole and the trench. Finally, metallic material is deposited into the via hole and the trench to form a via and a conductive line.

In the (dual) damascene process, a low temperature hard mask layer is formed over the low dielectric constant material layer. Since the hard mask layer is formed at a low temperature, properties of the low dielectric constant material layer remain unaffected. Hence, resistance stability of the via is improved. In addition, because denser adhesion promoter liner are formed on the interior sidewalls of the via hole (and trench), out-gassing from the low dielectric constant material layer into the via hole (and trench) is rare. Therefore, metallic material deposition is largely unimpeded and ‘via poisoning’ is avoided. Furthermore, the hard mask layer is formed at a low temperature leading to fewer dissociation of the low dielectric constant material. Consequently, severe out-gassing from the via hole is reduced considerably.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings, FIGS. 1A through 1C are schematic cross-sectional views showing the steps carried out in a conventional damascene process for forming a copper via; and

FIGS. 2A through 2F are schematic cross-sectional views showing the steps carried out in a dual damascene process for forming a copper via and a conductive line according to one preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

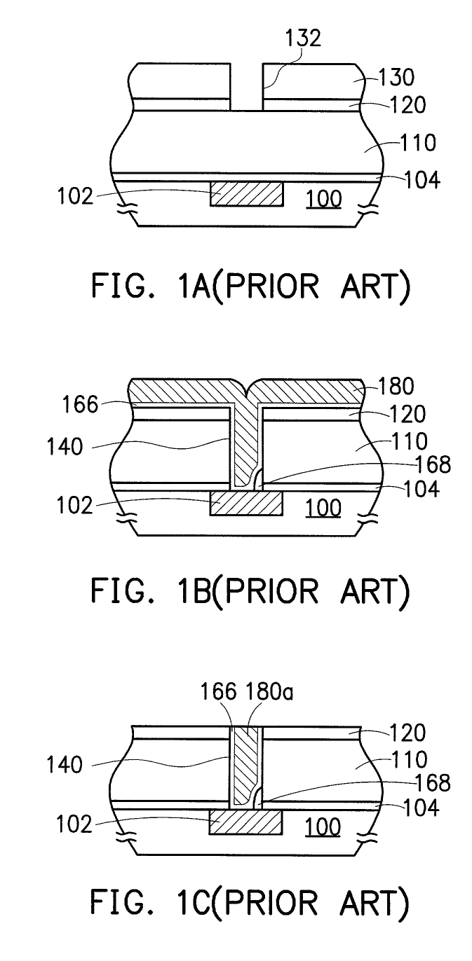

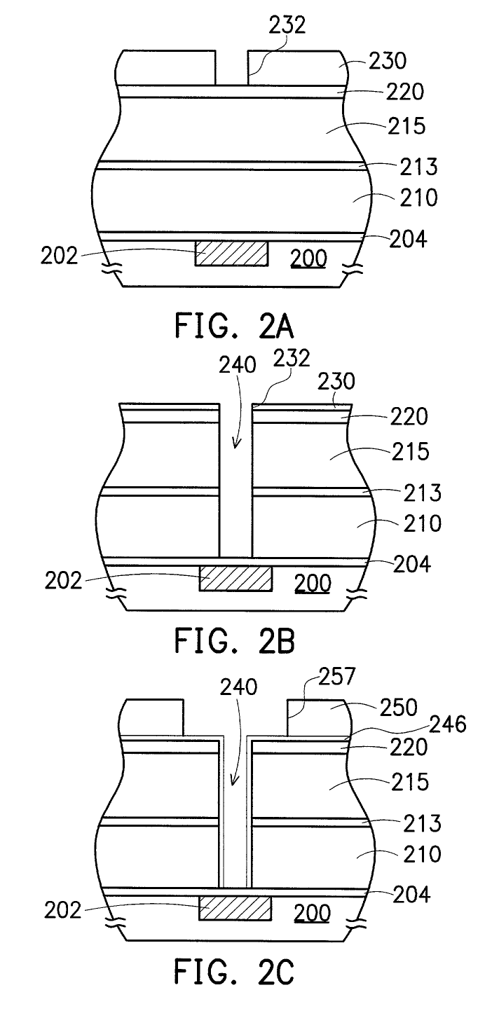

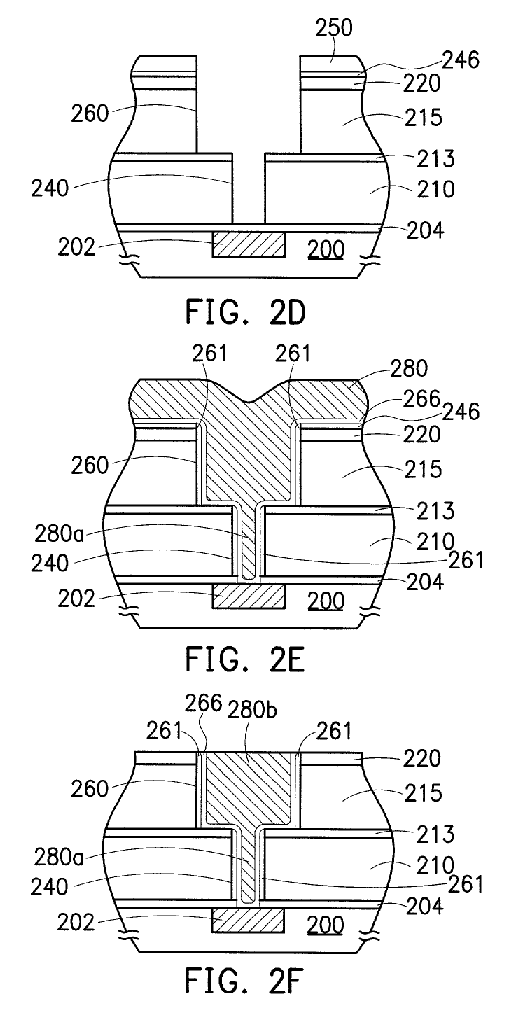

FIGS. 2A through 2F are schematic cross-sectional views showing the steps carried out in a dual damascene process for forming a copper via and a conductive line according to one preferred embodiment of this invention.

As shown in FIG. 2A, a substrate 200 having a conductive layer 202 thereon is provided. The conductive layer 202 can be a copper layer, for example. A passivation layer 204 is formed over the substrate 200. The passivation layer can be a silicon nitride layer, for example. A low dielectric constant material layer 210, an etching stop layer 213 and another low dielectric constant layer 215 are sequentially formed over the passivation layer 204. The low dielectric constant material layers 210 and 215 can be organic material layers made from SILK (trade name) or FLARE (trade name), for example. The etching stop layer 213 can be a silicon nitride layer, for example.

A low temperature hard mask layer 220 is formed over the low dielectric constant material layer 215. The hard mask layer 220 is formed at a low temperature of about 200° C. The hard mask layer 220 can be a silicon oxide layer formed, for example, by high-density plasma chemical vapor deposition (HDP-CVD). In a HDP-CVE process, an electrostatic chuck (ESC) can be used to grip the wafer and an un-biased process (no bias voltage applied to the wafer) can be used to lower deposition temperature. A patterned photoresist layer 230 is formed over the low temperature hard mask layer 220. The patterned photoresist layer 230 includes an opening 232 above the conductive layer 202.

As shown in FIG. 2B, using the photoresist layer 230 as an etching mask, the exposed hard mask layer 220 at the bottom of the opening 232 is etched. Thereafter, using the photoresist layer 230 and the hard mask layer 220 as an etching mask, the low dielectric constant material layer 215, the etching stop layer 213 and the low dielectric constant material layer 210 are sequentially etched. Ultimately, a via hole 240 that exposes a portion of the passivation layer 204 is formed above the conductive layer 202.

As shown in FIG. 2C, any residual photoresist layer 230 is removed. An antireflection coating 246 is formed over the substrate 200. The anti-reflection coating 216 can be a silicon oxynitride or an organic light-absorbing material, for example. A second patterned photoresist layer 250 is formed over the substrate 200. The patterned photoresist layer 250 includes a trench-like opening 257 that overlaps with the via hole 240.

As shown in FIG. 2D, the exposed anti-reflection coating 246 is removed. Using the photoresist layer 250 as an etching mask, the exposed low temperature hard mask layer 220 and the low dielectric constant material layer 215 is etched until the etching stop layer 213 is reached. Consequently, a trench 260 that exposes the via hole 240 is formed in the low dielectric constant material layer 215. The trench 260 and the via hole 240 together constitute a dual damascene opening.

As shown in FIG. 2E, an adhesion promoter liner 261 is formed on the interior walls of the trench 260 and the via hole 240. The adhesion promoter liner 261 can be, for example, AP-4000 or AP-8000 manufactured by Dow Chemical Corporation. The adhesion promoter liner 261 is formed, for example, by spin-coating the adhesion promoter agent (AP-4000 or AP-8000) onto the substrate 200, baking to solidify the agent and finally removing any excess agent on the trench 260 and via hole 240 by anisotropic etching.

A conformal barrier layer 266 is formed over the substrate 200. The barrier layer 266 can be a titanium nitride (TiN) or a tantalum nitride (TaN) layer, for example. A metallic layer 280 is formed by depositing metallic material over the substrate 100 and filling the via hole 240 and the trench 260. The metallic layer 280 can be copper and formed by electroplating. The metal in the via hole 240 becomes a via 280a. Here, the barrier layer 266 prevents the diffusion of metallic atoms from diffusing into the low dielectric constant material layers 210 and 215, especially the high-mobility copper atoms. To form the copper layer 280, a thin copper seed layer (not shown) is first deposited over the substrate 200. The substrate 200 is transferred to an electroplating bath so that a layer of copper is electroplated on top of the seed layer, is thereby filling the via hole 240 and the trench 260.

As shown in FIG. 2F, excess metallic material, barrier layer material and antireflection coating material outside the trench 260 are removed, for example, by chemical mechanical polishing (CMP) to form a conductive line 280b in the trench 260.

In the dual damascene process of this invention, a low temperature hard mask layer is formed over the low dielectric constant material layers. Since the hard mask layer is formed at a low temperature, properties of the low dielectric constant material layers remain unaffected. Hence, resistance stability of the via is improved. In addition, because denser adhesion promoter liner are formed on the interior walls of the via hole and trench, out-gassing from the low dielectric constant material layer into the via hole and trench is rare. Therefore, metallic material deposition is largely unimpeded and ‘via poisoning’ is avoided. Furthermore, the hard mask layer is formed at a low temperature leading to fewer dissociation of the low dielectric constant material. Consequently, severe out-gassing from the via hole is reduced considerably.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A damascene process for forming a via over a substrate having a conductive layer thereon, comprising the steps of:
forming a low dielectric constant material layer over the substrate;
forming a low temperature hard mask layer over the low dielectric constant material layer, wherein temperature for forming the hard mask layer is low enough to prevent any damaging effects on the properties of the low dielectric constant material layer;
patterning the low temperature hard mask layer to form an opening above the conductive layer;
etching the exposed low dielectric constant material layer using the low temperature hard mask layer to form a via hole;
forming an adhesion promoter liner on the interior walls of the via hole; and
depositing metallic material into the via hole to form a via.

2. The process of claim 1, wherein the low temperature hard mask layer has a formation temperature below 200° C.

3. The process of claim 1, wherein the step of forming the low temperature hard mask layer includes performing a high-density plasma chemical vapor deposition.

4. The process of claim 3, wherein the step of performing the high-density plasma chemical vapor deposition includes gripping the substrate with an electrostatic chuck and freeing the substrate from any bias voltage.

5. The process of claim 1, wherein material constituting the low temperature hard mask layer includes silicon oxide.

6. The process of claim 1, wherein before the step of forming the low dielectric constant material layer, further includes forming a passivation layer over the substrate, and after the step of forming the via hole, further includes etching the exposed passivation layer.

7. The process of claim 1, wherein material constituting the metallic layer includes copper.

8. The process of claim 1, wherein the step of depositing metallic material into the via hole further includes:
depositing a metallic material over the substrate by electroplating so that the via hole is filled; and
removing excess metallic material outside the via hole.

9. The process of claim 8, wherein the step of depositing metallic material over the substrate includes depositing copper and before the step of depositing metallic material further includes forming a copper seed layer.

10. The process of claim 8, wherein the step of removing excess metallic material outside the via hole includes performing chemical-mechanical polishing.

11. A dual damascene process for forming a via over a substrate having a conductive layer thereon, comprising the steps of:
forming a low dielectric constant material layer over the substrate;
forming a low temperature hard mask layer over the low dielectric constant material layer, wherein temperature for forming the hard mask layer is low enough to prevent any damaging effects on the properties of the low dielectric constant material layer;
patterning the low temperature hard mask layer to form an opening above the conductive layer;
etching the exposed low dielectric constant material layer using the low temperature hard mask as a mask to form a via hole;
etching a trench in the low temperature hard mask layer and the low dielectric constant material layer, wherein the trench overlaps with the via hole and the trench together with the via hole form a dual damascene opening;
forming an adhesion promoter liner on the interior walls of the dual damascene opening; and
depositing metallic material into the dual damascene hole to form a via and a conductive line.

12. The process of claim 11, wherein the low temperature hard mask layer has a formation temperature below 200° C.

13. The process of claim 11, wherein the step of forming the low temperature hard mask layer includes performing a high-density plasma chemical vapor deposition.

14. The process of claim 13, wherein the step of performing the high-density plasma chemical vapor deposition includes gripping the substrate with an electrostatic chuck and freeing the substrate from any bias voltage.

15. The process of claim 11, wherein material constituting the low temperature hard mask layer includes silicon oxide.

16. The process of claim 11, wherein before the step of forming the low dielectric constant material layer, further includes forming a passivation layer over the substrate, and after the step of forming the via hole, further includes etching the exposed passivation layer.

17. The process of claim 11, wherein the low dielectric constant material layer is a composite layer that includes a first dielectric layer below, an etching stop layer in the middle and a second dielectric layer at the top, and etching can stop at the etching stop layer in the trench-forming step.

18. The process of claim 11, wherein the step of etching a trench in the low dielectric constant material layer includes:
forming an anti-reflection coating over the substrate;
forming a patterned photoresist layer over the anti-reflection coating, wherein the patterned photoresist layer has a trench-like opening that exposes the via hole; and
removing the exposed anti-reflection coating, the low temperature hard mask layer and a portion of the low dielectric constant material layer using the photoresist layer as a mask to form the trench.

19. The process of claim 11, wherein material constituting the metallic layer includes copper.

20. The process of claim 11, wherein the step of depositing metallic material into the dual damascene process includes the sub-steps of:
depositing a metallic material over the substrate by electroplating so that the dual damascene hole is filled; and
removing excess metallic material outside the dual damascene hole.

21. The process of claim 20, wherein the step of depositing metallic material over the substrate includes depositing copper and before the step of depositing metallic material further includes forming a copper seed layer.

22. The process of claim 20, wherein the step of removing excess metallic material outside the dual damascene hole includes performing chemical-mechanical polishing.
